(19) United States
(12) Patent Application Publication
(10) Pub. No.: US 2006/0263985 A1
(43) Pub. Date: Nov. 23, 2006

(54) METHOD OF FABRICATING A SEMICONDUCTOR DEVICE

(75) Inventors: Nam-Jung KANG, Gyeonggi-do, (KR); Ji-Young KIM, Gyeonggi-do, (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do, (KR)

(21) Appl. No.: 11/383,722

(22) Filed: May 16, 2006

(30) Foreign Application Priority Data
May 20, 2005 (KR) 2005-0042456

(51) Int. Cl. H01L 21/8234

(52) U.S. Cl. 438/275

(57) ABSTRACT

A method of fabricating a semiconductor device to prevent the profiles of source/drain regions from being deformed due to the thermal budget. The method can simplify the overall process of fabricating a semiconductor device by reducing the number of processing steps of forming a photoresist pattern as an ion implantation mask, and can reduce the variations of the transistor characteristics.

### CROSS-REFERENCE TO RELATED PATENT APPLICATION

This application claims the benefit of Korean Patent Application No. 10-2005-0042456, filed on May 20, 2005, in the Korean Intellectual Property Office, the disclosure of which is incorporated herein in its entirety by reference.

### BACKGROUND OF THE INVENTION

1. Field of the Invention

The present invention relates to a method of fabricating a semiconductor device, and more particularly, to a method of fabricating a semiconductor device having bitline contact plugs and bitlines.

2. Description of the Related Art

As patterns used to fabricate semiconductor devices become more sophisticated, an increasing number of these semiconductor devices are manufactured by forming a contact in a cell region of a semiconductor substrate and forming a contact in a peripheral circuit region of the semiconductor substrate in separate processes dealing with different etching targets. In other words, in the cell region, a contact hole may be formed by simply etching an interlayer insulation layer comprised of an oxide layer, while, in the peripheral circuit region, a contact hole may be formed by etching both the interlayer insulation layer and a gate hard mask comprised of a nitride layer. However, when the etching process for forming a contact hole in the cell region and the etching process for forming a contact hole in the peripheral circuit region are performed separately from each other, an overall process of fabricating the semiconductor device may become complicated and the fabrication costs may undesirably increase because of the need to form photoresist patterns used for forming a bitline contact in the cell region and in the peripheral circuit region.

Therefore, a method has been suggested of fabricating a semiconductor device in which a process of forming a bitline contact in a cell region and a process of forming a contact connected to an NMOS source/drain region in a peripheral circuit region are combined and a contact connected to a gate conductive layer in a peripheral circuit region and a contact connected to a PMOS source/drain region in the peripheral circuit region are formed. This method will now be described in further detail with reference to FIGS. 1 through 7.

FIGS. 1 through 7 are cross-sectional views illustrating a conventional method of making a semiconductor device having bitline contact plugs and bitlines. The formation of bitline contact plugs and bitlines in a cell region and in a peripheral circuit region will now be described in detail with reference to these figures.

Referring to FIG. 1, a device isolation layer 15 is formed on a semiconductor substrate 10, and a plurality of gate electrode patterns, which include a gate insulation layer 20, a gate conductive layer 25, and a gate hard mask 30, are formed on the semiconductor substrate 10. Thereafter, gate spacers 35 are formed on both sidewalls of each of the gate electrode patterns. A plurality of source/drain regions 40 are formed in a cell region by implanting dopant ions into the semiconductor substrate 10 between the gate electrode patterns in the cell region.

Thereafter, a first photoresist pattern 45 is formed on the semiconductor substrate 10 so that an NMOS area in a peripheral circuit region is exposed. A plurality of N-type source/drain regions 50 are formed by implanting N-type dopant ions into the semiconductor substrate 10 using the first photoresist pattern 45 as an ion implantation mask. Thereafter, the first photoresist pattern 45 is removed.

Referring to FIG. 2, a second photoresist pattern 55 having an opening that exposes a PMOS area in the peripheral circuit region is formed on the semiconductor substrate 10. Thereafter, a plurality of P-type source/drain regions 60 are formed by implanting P-type dopant ions into the semiconductor substrate 10 using the second photoresist pattern 55 as an ion implantation mask. Thereafter, the second photoresist pattern 55 is removed.

Referring to FIG. 3, a first interlayer insulation layer 65 is formed to fill spaces between the gate electrode patterns. Thereafter, the first interlayer insulation layer 65 is planarized. Then, a plurality of contact holes are formed in a self-alignment manner to expose the respective source/drain regions in the cell region. Thereafter, a doped polysilicon layer is formed to fill the contact holes. Next, the doped polysilicon layer is planarized so that the top surface of the gate hard mask 30 is exposed. Thereafter, a plurality of landing pads 70 are formed to contact the respective source/drain regions 40 in the cell region.

Referring to FIG. 4, a second interlayer insulation layer 75 is formed on the semiconductor substrate 10 and, if necessary, is planarized. Thereafter, a third photoresist pattern 80 is formed on the second interlayer insulation layer 75 so that the landing pads 70 in the cell region are exposed and the N-type source/drain regions 50 in the peripheral circuit region are exposed in a contact-type manner. The second interlayer insulation layer 75 is etched, using the third photoresist pattern 80 as an etching mask, thereby forming a plurality of bitline contact holes 82 that expose the respective landing pads 70. Also, a plurality of first contact holes 84 are formed to expose the respective N-type source/drain regions 50 by etching the first and second interlayer insulation layers 65 and 75. In this manner, a process of forming a bitline contact and a process of forming a contact connected to an NMOS source/drain in a peripheral area may be combined.

Still referring to FIG. 4, a high concentration of N+ dopant ions are implanted into the semiconductor substrate 10 by using the third photoresist pattern 80 as an ion implantation mask, thereby forming a high-concentration N⁺ impurity region 52 in each of the N-type source/drain regions 50. The high-concentration N⁺ impurity region 52 reduces contact resistance. Thereafter, the third photoresist pattern 80 is removed.

Referring to FIG. 5, a fourth photoresist pattern 90 is formed so that the P-type source/drain regions 60 are exposed in the contact-type manner. Thereafter, the second interlayer insulation layer 75 and the gate hard mask 30 are etched using the fourth photoresist pattern 90 as an etching mask, thereby forming a plurality of second contact holes 92 that expose portions of the gate conductive layer 25. Thereafter, the first and second interlayer insulation layers 65 and 75 are etched, thereby forming a plurality of third contact holes 94 that expose the respective P-type source/drain regions 60.

A high concentration of P+ dopant ions are implanted into the semiconductor substrate 10 using the fourth photoresist pattern 90 as an ion implantation mask, thereby forming a high-concentration P⁺ impurity region 62 in each of the P-type source/drain regions 60. Thereafter, the fourth photoresist pattern 90 is removed.

Referring to FIG. 6, a conductive layer 95 is deposited on the semiconductor substrate 10 to fill the bitline contact holes 82 and the first, second, and third contact holes 84, 92, and 94.

Referring to FIG. 7, the conductive layer 95 is patterned, thereby forming a plurality of bitline contact plugs 95a that fill the respective bitline contact holes 82, first, second, and third contact plugs 95b, 95c, and 95d that fill the first, second, and third contact holes 84, 92, and 94, respectively, and a plurality of bitlines 95e that are connected as one body to the bitline contact plugs 95a and the first, second, and third contact plugs 95b, 95c, and 95d.

In the conventional method of fabricating a semiconductor device, the N-type source/drain regions 50 and the P-type source/drain regions 60 are formed in the peripheral circuit region, and then the first and second interlayer insulation layers 65 and 75 are formed. Thus, if the first and second interlayer insulation layers 65 and 75 are formed of boron phosphorus silicate glass (BPSG) and then are planarized by performing a reflowing process at very high temperatures, the dopant ions implanted into the N-type source/drain regions 50 and the P-type source/drain regions 60 may diffuse deeply into the semiconductor substrate 10, and thus, the profiles of the N-type source/drain regions 50 and the P-type source/drain regions 60 may be deformed due to the heat generated during the reflowing process. Therefore, a heat budget in the reflowing process and an annealing process must be considered before performing the reflowing process and an annealing process in order to prevent the profiles of the N- type source/drain regions 50 and the P⁻ type source/drain regions 60 from being deformed during the reflowing process and the annealing process. However, the first and second interlayer insulation layers 65 and 75 may not be able to be sufficiently planarized when reflowed at low temperatures, and the landing pad 70 may increase leakage current of a plurality of transistors in the cell region when annealed at low temperatures. Leakage current is partly responsible for deterioration of the electrical performance of a semiconductor device and reduction of semiconductor device yield.

In addition, in the conventional method of fabricating a semiconductor device, different photoresist patterns are used as ion implantation masks for forming the source/drain regions 40 in the cell region, forming the N-type source/drain regions 50 in an NMOS area, forming the P-type source/drain regions 60 in a PMOS area, forming the N⁺ impurity region 52 in each of the N-type source/drain regions 50, and forming the P⁺ impurity region 62 in each of the P-type source/drain regions 60. Accordingly, five different processing steps of forming 5 photoresist patterns are needed, which makes the overall semiconductor fabrication process complicated and increases overall manufacturing costs.

Moreover, if the third or fourth photoresist pattern 80 or 90 is misaligned, the distance between the gate spacer 35 and the N⁺ impurity region 52 or the P⁺ impurity region 62 becomes irregular and asymmetric. Accordingly, the transistor may suffer any number of problems such as a plug effect, due to misalignment of the impurity regions. The plug effect is a phenomenon in which a threshold voltage decreases rapidly or an off current is generated when an implantation process is carried inadequately due to misalignment with regard to the concentration of layers. Characteristics of the transistors in the peripheral circuit region may vary due to the plug effect.

### SUMMARY

According to some embodiments of the present invention, an overall semiconductor fabrication process can be simplified by reducing the number of processing steps for forming ion implantation masks and the variation of the characteristics of a plurality of transistors due to a plug effect can be minimized.

According to an embodiment of the present invention, a method of fabricating a semiconductor device includes: forming a plurality of gate electrode patterns on a semiconductor substrate on which an active area is defined; forming an interlayer insulation layer on the gate electrode patterns; forming a plurality of contact holes on both sides of each of the gate electrode patterns in a self-alignment manner by etching a predetermined portion of the interlayer insulation layer located above the active area in an area-type manner to expose the gate electrode patterns; and forming a plurality of source/drain regions in the semiconductor substrate by implanting ions into the semiconductor substrate through the contact holes.

In this method, the source/drain regions are formed after the interlayer insulation layer is formed. Thus, the profiles of the source/drain regions can be prevented from being adversely affected by the heat budget even when the interlayer insulation layer is formed of BPSG and a reflowing process is performed on the interlayer insulation layer at high temperatures.

When an element formed on an active area of a semiconductor substrate is etched in an ‘area-type’ manner, substantially the entire surface of an active area may be exposed. On the other hand, when the element is etched in a ‘contact-type’ manner, only part of the active area may be exposed.

According to another embodiment of the present invention, a method of fabricating a semiconductor device includes: forming a plurality of gate electrode patterns in a peripheral circuit region of a semiconductor substrate on which an active area is defined; forming an interlayer insulation layer on the gate electrode patterns; forming a plurality of first contact holes on both sides of the gate electrode pattern in an NMOS area of the peripheral circuit region in a self-alignment manner by etching a predetermined portion of the interlayer insulation layer located above part of the active area defining the NMOS area in an area-type manner so that the gate electrode pattern in the NMOS area is exposed; forming a plurality of N-type source/drain regions in the semiconductor substrate by implanting N-type dopant ions into the semiconductor substrate through the first contact holes; forming a plurality of second contact holes on both sides of the gate electrode pattern in a PMOS area of the peripheral circuit region in the self-alignment manner by etching a predetermined portion of the interlayer insulation layer located above part of the active area defining the PMOS area in an area-type manner so that the gate electrode pattern in the PMOS area is exposed; and forming a plurality of P-type source/drain regions in the semiconductor substrate by implanting P-type dopant ions into the semiconductor substrate through the second contact holes.

The method may also include forming a high-concentration N⁺ impurity region in each of the N-type source/drain regions by implanting a high concentration of N⁺ ions into the semiconductor substrate through the first contact holes, after the forming of the N-type source/drain regions. Accordingly, it is possible to simplify the overall process of fabricating a semiconductor device by reducing the number of times a process of forming a photoresist pattern, which would be used as an ion implantation mask, is performed. In the forming of the first contact holes, the forming of the N-type source/drain regions, and the forming of the high-concentration N⁺ impurity region, the same photoresist pattern is used.

The method may also include forming a high-concentration P⁺ impurity region in each of the P⁻ type source/drain regions by implanting a high concentration of P⁺ ions into the semiconductor substrate through the second contact holes, after the forming of the P-type source/drain regions.

In the forming of the second contact holes, the forming of the P-type source/drain regions, and the forming of the high-concentration P⁺ impurity region, the same photoresist pattern may be used. Accordingly, it is possible to reduce the variation of the characteristics of a plurality of transistors in the peripheral circuit region due to the misalignment of impurity regions by etching the interlayer insulation layer in the area-type manner to form the source/drain regions and the high concentration impurity regions.

According to yet another embodiment of the present invention, a method of fabricating a semiconductor device includes: forming a plurality of gate electrode patterns on a semiconductor substrate which is divided into a cell region and a peripheral circuit region and on which an active area is defined, the gate electrode patterns each being a stack of a gate insulation layer, a gate conductive layer, and a gate hard mask; forming a plurality of source/drain regions in the cell region of the semiconductor substrate; forming a first interlayer insulation layer on the semiconductor substrate to fill spaces between the gate electrode patterns; forming a plurality of contact holes by etching the first interlayer insulation layer so that the source/drain regions in the cell region are exposed and forming a plurality of landing pads in the respective contact holes; forming a second interlayer insulation layer on the first interlayer insulation layer, the landing pads, and the gate electrode patterns; forming a first photoresist pattern on the second interlayer insulation layer so that the landing pads on the second interlayer insulation layer are exposed and that a predetermined portion of the second interlayer insulation layer located above part of the active area defining an NMOS area of the peripheral circuit region is exposed in an area-type manner; forming a plurality of bitline contact holes that expose the respective landing pads by etching the second interlayer insulation layer using the first photoresist pattern as an etching mask, and forming a plurality of first contact holes on both sides of the gate electrode patterns in the NMOS area in a self-alignment manner by etching the first and second interlayer insulation layers so that the gate electrode patterns in the NMOS area are exposed; forming a plurality of N-type source/drain regions in the NMOS area by implanting N-type dopant ions into the semiconductor substrate using the first photoresist pattern as an ion implantation mask and forming a high-concentration N⁺ impurity region in each of the N-type source/drain regions by implanting a high concentration of N⁺ ions into the semiconductor substrate; and removing the first photoresist pattern.

In this method, the source/drain regions in the peripheral circuit region are formed after the first and second interlayer insulation layers and the landing pad are formed. Therefore, the profiles of the source/drain regions can be prevented from being adversely affected by heat budget in a reflowing process performed on the first and second interlayer insulation layers and in an annealing process performed on the landing pad. In addition, the formation of the source/drain regions and the formation of the high concentration impurity regions can be combined. As a result, the overall process of fabricating a semiconductor device can be simplified by reducing the number of processing steps for forming a photoresist pattern as an ion implantation mask. Moreover, since the first and second interlayer insulation layers are etched in the area-type manner to form the source/drain regions and the high concentration impurity regions, the variation of the characteristics of a plurality of transistors in the peripheral circuit region due to the misalignment of the impurity regions can be minimized.

### BRIEF DESCRIPTION OF THE DRAWINGS

The above and other features and advantages of the present invention will become more apparent by describing in detail an exemplary embodiment thereof with reference to the attached drawings in which:

FIGS. 1 through 7 are cross-sectional views illustrating a conventional method of fabricating a semiconductor device having bitline contact plugs and bitlines; and

FIGS. 8 through 13 are cross-sectional views illustrating a method of fabricating a semiconductor device according to an exemplary embodiment of the present invention.

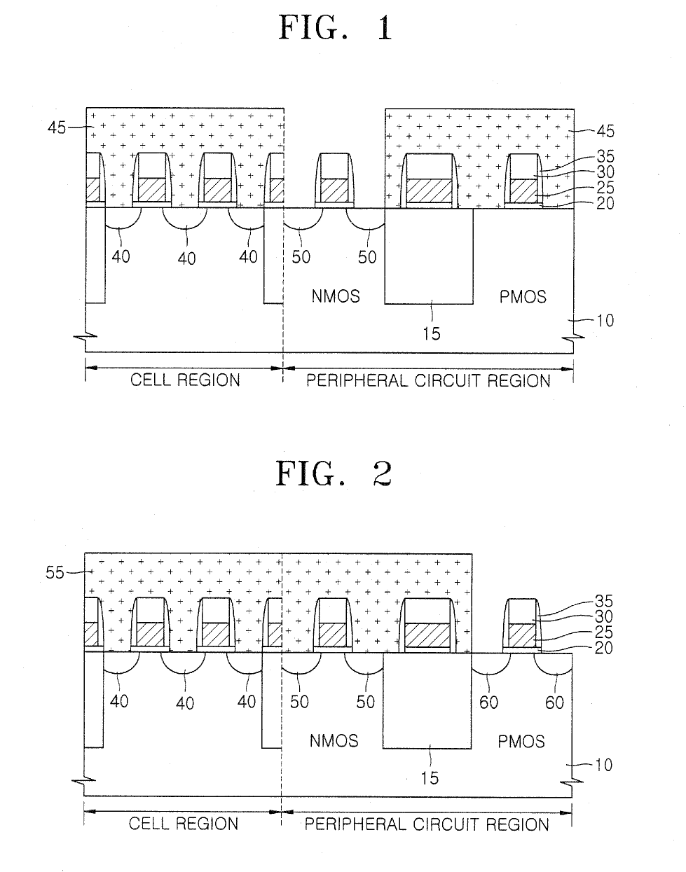

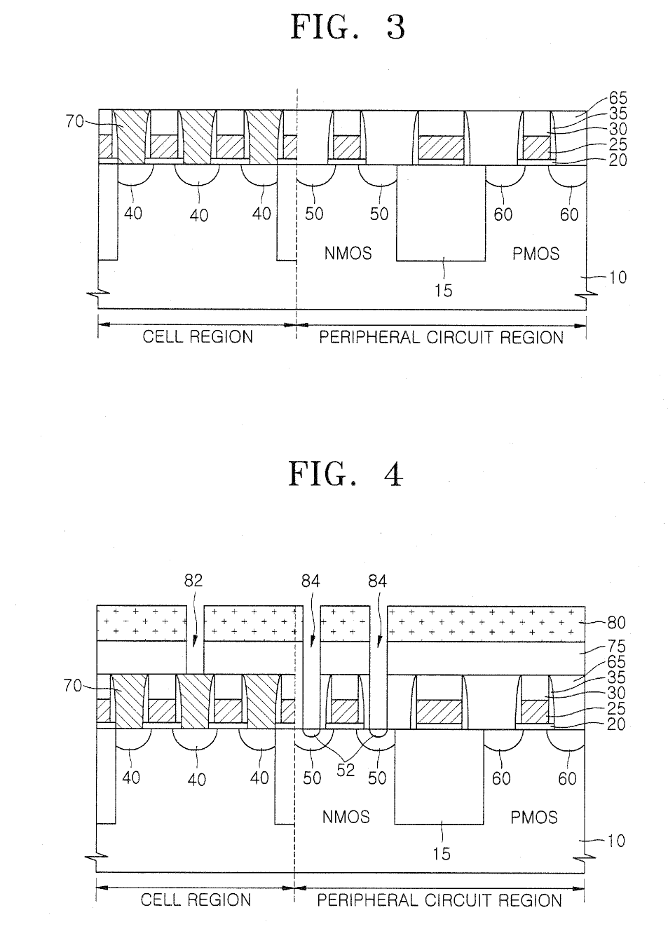

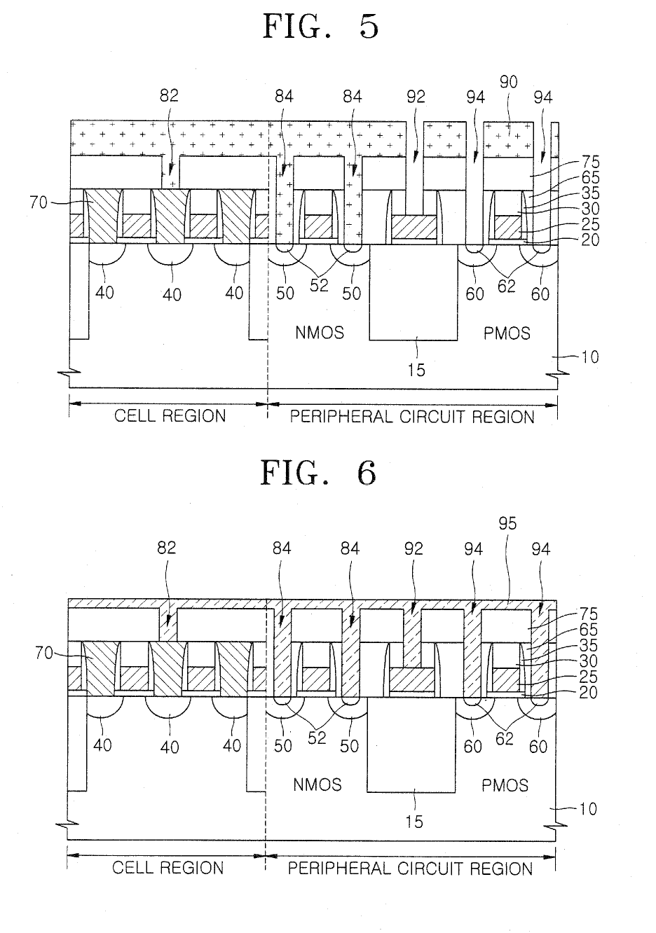

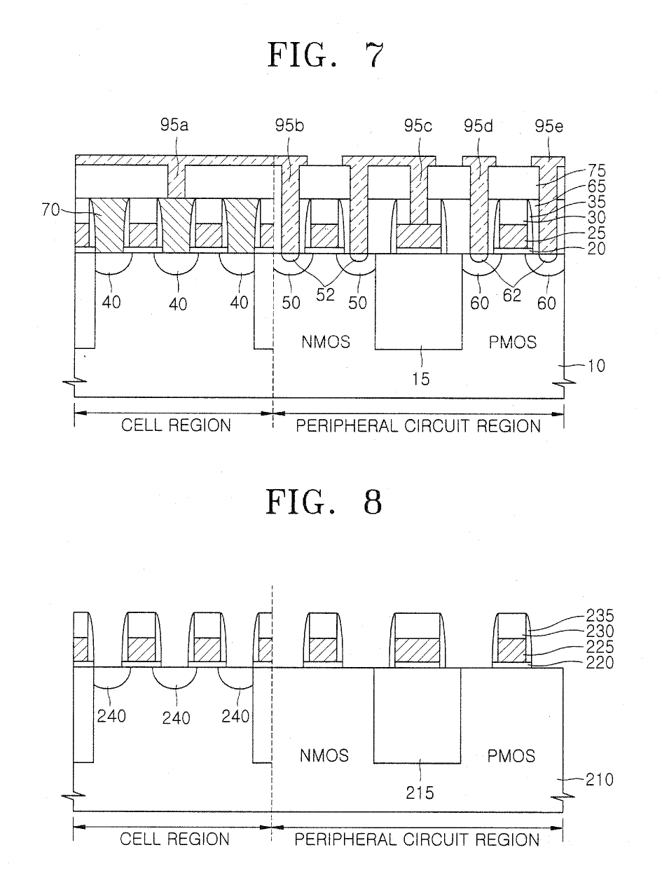

### DETAILED DESCRIPTION

The present invention will now be described more fully with reference to the accompanying drawings in which exemplary embodiments of the invention are shown. This invention may, however, be embodied in many different forms and should not be construed as being limited to the embodiment set forth herein. Rather, this embodiment is provided so that this disclosure will be thorough and complete, and will fully convey the scope of the invention to those skilled in the art. In the drawings, the forms of elements are exaggerated for clarity. To facilitate understanding, identical reference numerals have been used, where possible, to designate identical elements that are common to the figures.

FIGS. 8 through 13 are cross-sectional views illustrating a method of fabricating a semiconductor device according to an exemplary embodiment of the present invention.

Referring to FIG. 8, a device isolation layer 215, such as shallow trench isolation (STI), is formed on a semiconductor substrate 210, thereby defining an active area in a cell region and a peripheral circuit region. Thereafter, a plurality of gate electrode patterns, which may be each a stack of a gate insulation layer 220, a gate conductive layer 225, and a gate hard mask 230, are formed on the semiconductor substrate 210. Thereafter, gate spacers 235 are formed on both sidewalls of each of the gate electrode patterns. Thereafter, a plurality of source/drain regions 240 are formed in the cell region by implanting dopant ions into regions of the semiconductor substrate 210 between the gate electrode patterns in the cell region.

The gate insulation layer 220 comprises, for example, a silicon oxide layer, and the gate conductive layer 225 comprises, for example, polysilicon, tungsten, tungsten silicide, tungsten nitride, or a combination thereof. The gate hard mask 230 prevents the gate conductive layer 225 from being damaged in a subsequent process of forming, for example, a plurality of contact holes and also prevents the gate conductive layer 225 and a plurality of contact plugs that will be formed in a subsequent process from being electrically short-circuited. For this, the gate hard mask 230 may be formed of a silicon oxynitride layer, a silicon oxide layer, or a silicon nitride layer. The gate spacers 235 are formed by depositing a spacer formation layer along the profiles of the gate electrode patterns and performing a blanket etching process on the spacer formation layer. The gate spacers 235 prevent the gate electrode patterns from being damaged in a subsequent process of forming, for example, a plurality of contact holes. Therefore, the gate spacers 235 may comprise a nitride layer, a stack of a silicon oxide layer and a nitride layer, or a stack of a nitride layer, an oxide layer, and a nitride layer. Here, examples of the nitride layer used to form the gate spacers 235 include a silicon oxynitride layer or a silicon nitride layer.

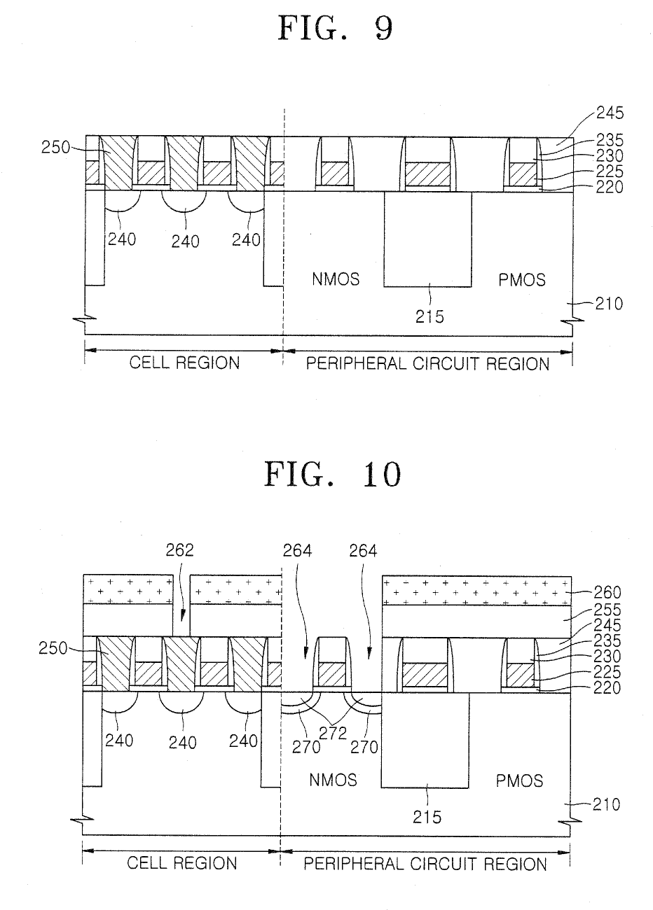

Referring to FIG. 9, a first interlayer insulation layer 245 is formed to fill spaces between the gate electrode patterns. Thereafter, the first interlayer insulation layer 245 is planarized. The first interlayer insulation layer 245 may be formed of a silicon oxide layer, such as a BPSG layer, a boron silicate glass (BSG) layer, a phosphorous silicate glass (PSG) layer, a plasma enhanced-tetraethylorthosilicate (PE-TEOS) layer, or a high density plasma (HDP) layer. The first interlayer insulation layer 245 may be planarized through a reflowing or chemical mechanical polishing (CMP) process. At this stage of fabrication, a plurality of source/drain regions are yet to be formed in a peripheral circuit region, and thus, the reflowing process can be performed at high temperatures.

Thereafter, a plurality of self-aligned contact holes are formed in a self-alignment manner to expose the respective source/drain regions 240 in the cell area. Then, a conductive layer is formed to fill the self-aligned contact holes. Afterward, the conductive layer is planarized until the top surface of the gate hard mask 230 is exposed. In this manner, a plurality of landing pads 250 are formed in the self-aligned contact holes to contact the respective source/drain regions 240. The landing pads 250 may include a doped polysilicon layer, a tungsten layer, a Ti layer, or a TiN layer. Some of the landing pads 250, particularly, the landing pads 250 located in the middle of the cell region, are connected to a plurality of bitline contact plugs that will be formed later in a subsequent process, and the rest of the landing pads 250 will be connected to a plurality of storage node contact plugs.

Thereafter, an annealing process is carried out on the landing pads 250. At this stage of fabrication, a plurality of source/drain regions are still yet to be formed in the peripheral circuit region. Thus, the annealing process can be performed on the landing pads 250 at sufficiently high temperatures to reduce leakage current of a plurality of transistors in the cell region, for example, at a temperature of about 850° C. In this manner, it is possible to fabricate a semiconductor device having excellent leakage current characteristics.

Referring to FIG. 10, a second interlayer insulation layer 255 is formed on the first interlayer insulation layer 245, the landing pads 250, and the gate electrode patterns. The second interlayer insulation layer 255 may be formed of an oxide layer, such as a BPSG layer, a BSG layer, a PSG layer, a PE-TEOS layer, or an HDP layer. The second interlayer insulation layer 255 may be reflowed even at high temperatures because a plurality of source/drain regions are still yet to be formed in the peripheral circuit region. Thereafter, a first photoresist pattern 260 having openings that expose the landing pads 250 under the second interlayer insulation layer 255 in the cell region and substantially the entire surface of the active area defining an NMOS area of the peripheral circuit region, i.e., in an ‘area-type’ manner. When an element such as an insulating layer formed on an active area of a semiconductor substrate is etched in an ‘area-type’ manner, substantially the entire surface of an active area defining, e.g., an NMOS area, may be exposed. On the other hand, when the element is etched in a ‘contact-type’ manner, only part of the active area may be exposed.

As described above, if the first photoresist pattern 260 is formed in a ‘contact-type’ manner, it can only partially expose the active area, e.g., only a portion of the active area for forming a contact plug. In the present embodiment, the first photoresist pattern 260 is formed in the ‘area-type’ manner. Thus, substantially the entire surface of the active area defining an NMOS area of the peripheral circuit region is exposed.

The second interlayer insulation layer 255 is etched, using the first photoresist pattern 260 as an etching mask, thereby forming a plurality of bitline contact holes 262 that expose the respective landing pads 250. Also, the first and second interlayer insulation layers 245 and 255 are etched until the top surface of the semiconductor substrate 210 is exposed. As a result, a plurality of first contact holes 264 are formed on both sides of each of the gate electrode patterns in the NMOS area and self-aligned with the exposed gate electrode patterns. The first contact holes 264 on both sides of the gate electrode patterns are described above as separate contact holes. However, the first contact holes 264 on both sides of the gate electrode patterns may collectively form a single opening that exposes regions of the semiconductor substrate 210 on both sides of the gate electrode patterns and a top surface of the gate hard mask 230 as shown in FIG. 10.

Thereafter, N-type dopant ions are implanted into the semiconductor substrate 210, using the first photoresist pattern 260 as an ion implantation mask, thereby forming a plurality of N-type source/drain regions 270 in the NMOS area of the peripheral circuit region.

Thereafter, high concentration N⁺ dopant ions are implanted into the semiconductor substrate 210, using the first photoresist pattern 260 again as an ion implantation mask, thereby forming a high-concentration N⁺ impurity region 272 in each of the N-type source/drain regions 270. The high concentration N⁺ dopant ions are implanted at a concentration of about E×10¹⁵ to E×10¹⁶ atoms/cm³ and at an energy of about 30 KeV to about 40 KeV. Thereafter, the first photoresist pattern 260 is removed.

As described above, in the present embodiment, the process of forming the N- type source/drain regions 270 and the process of forming the high-concentration N⁺ impurity region 272 in each of the N-type source/drain regions 270 are combined, i.e., performed using the same ion implantation mask, while, in the prior art, they would have been carried out separately from each other. Therefore, it is possible to simplify the overall process of fabricating a semiconductor device by reducing the number of processing steps for forming a photoresist pattern as an ion implantation mask.

In addition, in the present embodiment, the N-type source/drain regions 270 are formed after the first and second interlayer insulation layers 245 and 255 and the first contact holes 264 are formed. Thus, the N-type source/drain regions 270 may not be damaged in an etching process for forming the first contact holes 264, and dopant ion loss during the etching process can be prevented. Accordingly, it is possible to considerably increase contact resistance.

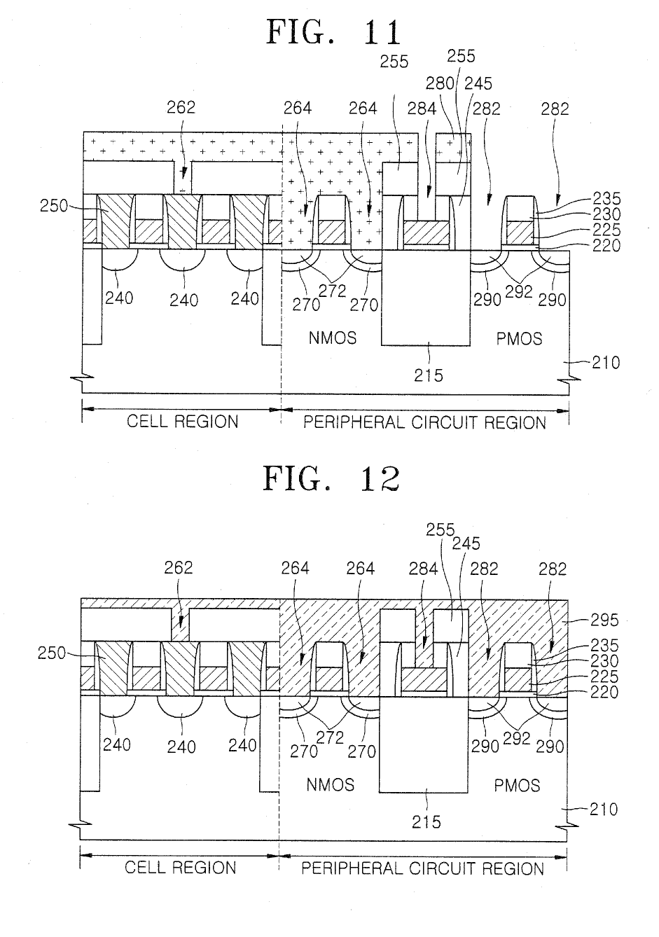

Referring to FIG. 11, a second photoresist pattern 280 is formed in the ‘area-type’ manner so that substantially the entire surface of the active area defining a PMOS area of the peripheral circuit region is exposed. Thereafter, a plurality of second contact holes 282 are formed on both sides of each of the gate electrode patterns in the PMOS area by etching the first and second interlayer insulation layers 245 and 255, using the second photoresist pattern 280 as an etching mask. Also, a plurality of third contact holes 284 are formed to expose the respective portions of the gate conductive layer 225 by etching the second interlayer insulation layer 255 10 and the gate hard mask 230.

Thereafter, P⁻ type dopant ions are implanted into the semiconductor substrate 210, using the second photoresist pattern 280 as an ion implantation mask, thereby forming P-type source/drain regions 290 in the PMOS area of the peripheral circuit region. Thereafter, high concentration P⁺ dopant ions are implanted into the semiconductor substrate 210, using the second photoresist pattern 280 again as an ion implantation mask, thereby forming a high-concentration P⁺ impurity region 292 in each of the P-type source/drain regions 290. The high concentration P⁺ dopant ions are implanted at a concentration of about E×10¹⁵ to about E×10¹⁶ atoms/cm³ and at an energy of about 30 KeV to about 40 KeV. Thereafter, the second photoresist pattern 280 is removed.

As described above, in the present embodiment, the process of forming the P-type source/drain regions 290 and the process of forming the high-concentration P⁺ impurity region 292 in each of the P-type source/drain regions 290 are combined, while, in the prior art, they would have been carried out separately from each other. Therefore, it is possible to simplify the overall process of fabricating a semiconductor device by reducing the number of processing steps, e.g., for forming a photoresist pattern as an ion implantation mask.

In addition, in the present embodiment, the P-type source/drain regions 290 are formed after the first and second interlayer insulation layers 245 and 255 and the second contact holes 282 are formed. Thus, the P-type source/drain regions 290 may not be damaged in an etching process for forming the second contact holes 282, and dopant ion loss during the etching process can be prevented. Accordingly, it is possible to considerably increase contact resistance.

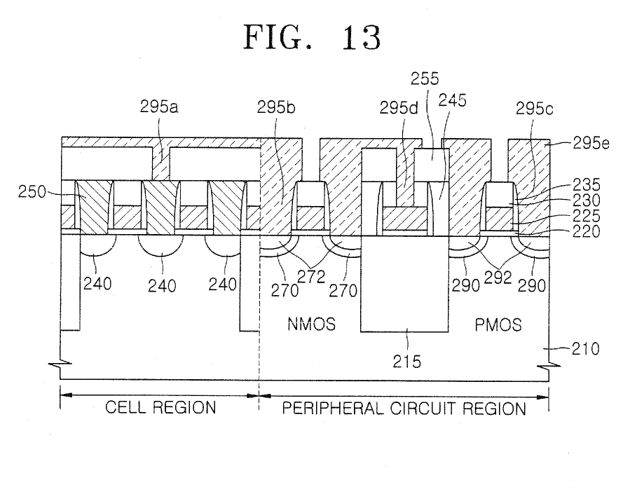

Referring to FIG. 12, a conductive layer 295 is deposited on the semiconductor substrate 210 to fill the bitline contact holes 262 and the first, second, and third contact holes 264, 282, and 284. The conductive layer 295 may be formed of a conductive material including, but not limited to, doped polysilicon, tungsten, or tungsten nitride.

Referring to FIG. 13, the conductive layer 295 is patterned, thereby forming a plurality of contact plugs 295a that fill the respective bitline contact holes 262, first, second, and third contact plugs 295b, 295c, and 295d that fill the first, second, and third contact holes 264, 282, and 284, respectively, and a plurality of bitlines 295e that may be connected as one body to the contact plugs 295a and the first, second, and third contact plugs 295b, 295c, and 295d. The conductive layer 295 may be etched until the gate hard mask 230 is exposed.

In some embodiments of the present invention, the N-type source/drain regions 270 or the P-type source/drain regions 290 are formed in the peripheral circuit region after the first and second interlayer insulation layers 245 and 255 are formed. Thus, the profiles of the N-type source/drain regions 270 or the P-type source/drain regions 290 may not be deformed due to the heat generated during a reflowing process even when the first and second interlayer insulation layers 245 and 255 are reflowed at high temperatures to be planarized. Therefore, it is possible to planarize the first and second interlayer insulation layers 245 and 255 by performing a reflowing process on the first and second interlayer insulation layers 245 and 255 at high temperatures.

In addition, in some embodiments of the present invention, the N-type source/drain regions 270 or the P-type source/drain regions 290 are formed in the peripheral circuit region after the landing pads 250 are formed in the cell region. Thus, it is possible to carry out an annealing process on the landing pads 250 at sufficiently high temperatures to reduce leakage current of a plurality of transistors in the cell region. Therefore, it is possible to manufacture a semiconductor device having excellent leakage current characteristics.

Moreover, in some embodiments of the present invention, the process of forming the N-type source/drain regions 270 and the process of forming the N⁺ impurity region 262 may be combined, and the process of forming the P-type source/drain regions 290 and the process of forming the P⁺ impurity region 292 may be combined. Thus, a process of forming a photoresist pattern is carried out three (3) times, for example, while forming the source/drain regions 240 in the cell region. Accordingly, it is possible to simplify the overall process of fabricating a semiconductor device by reducing the number of times that the process of forming a photoresist pattern needs to be carried out.

Furthermore, the N⁺ impurity region 272 or the P⁺ impurity region 292 is generated by exposing the semiconductor substrate 210 in the area-type manner by etching and implanting ions into the exposed semiconductor substrate 210. Thus, it is possible to prevent an irregular distribution of the characteristics of a plurality of transistors by reducing the variations of the characteristics of the transistors due to the plug effect.

As described above, according to an embodiment of the present invention, a plurality of sources and drains are formed in a peripheral circuit region after first and second interlayer insulation layers and a plurality of landing pads are formed. Therefore, it is possible to prevent the profiles of the source/drain regions from being deformed due to a heat treatment in a reflowing process even when the first and second interlayer insulation layers are reflowed at high temperatures to be planarized. In addition, it is possible to carry out an annealing process on the landing pads at sufficiently high temperatures to reduce leakage current of a plurality of transistors in a cell region. Therefore, it is possible to manufacture a semiconductor device having excellent leakage current characteristics.

In some embodiments of the present invention, a process of forming a plurality of N-type source/drain regions in the peripheral circuit region and a process of forming an N⁺ impurity region in each of the N-type source/drain regions are combined together, and a process of forming a plurality of P-type source/drain regions in the peripheral circuit region and a process of forming a P+ impurity region in each of the P-type source/drain regions are combined together. Thus, it is possible to simplify the overall process of fabricating a semiconductor device and reduce the fabrication costs of the semiconductor device by reducing the number of times a process of forming a photoresist pattern is performed.

In addition, in the present invention, the N⁺ impurity region and the P⁺ impurity region are generated by implanting ions into a semiconductor substrate after exposing the semiconductor substrate in an ‘area-type’ manner, Thus, it is possible to prevent an irregular distribution of the characteristics of a plurality of transistors by reducing the variation of the transistor characteristics.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a semiconductor device, the method comprising:
forming a device isolation layer on a semiconductor substrate to define an active area;
forming a gate electrode pattern extending across the active area;
forming an interlayer insulation layer on the gate electrode pattern;
etching a portion of the interlayer insulation layer to expose substantially the entire surface of the active region, thereby forming a plurality of contact holes extending through the interlayer insulation layer on both sides of the gate electrode patterns and on a top of the gate electrode pattern, the plurality of contact holes self-aligned with the gate electrode patterns; and
forming a plurality of source/drain regions in the semiconductor substrate by implanting ions into the semiconductor substrate through the contact holes.

2. The method of claim 1, wherein the gate electrode pattern is formed in a peripheral circuit region on the semiconductor substrate.

3. The method of claim 1, which further comprises forming a high-concentration impurity region in the source/drain regions by implanting a high concentration of impurity ions into the semiconductor substrate through the contact holes.

4. The method of claim 1, wherein forming the contact holes comprises:
forming a photoresist pattern on the interlayer insulation layer so that the portion of the interlayer insulation layer located above the active area is exposed; and
etching the interlayer insulation layer using the photoresist pattern as an etching mask until the top surface of the semiconductor substrate is exposed, and
forming the source/drain regions comprises implanting ions into the semiconductor substrate using the photoresist pattern as an ion implantation mask.

5. The method of claim 4, which further comprises forming a high-concentration impurity region in the source/drain regions by implanting a high concentration of impurity ions into the semiconductor substrate using the photoresist pattern as an ion implantation mask, which has been used as the ion implantation mask for forming the source/drain regions.

6. The method of claim 1, which further comprises:
depositing a conductive layer to fill the contact holes to form contact plugs wherein bitlines that connect to the contact plugs comprise one body by patterning the conductive layer.

7. A method of fabricating a semiconductor device, the method comprising:
forming a plurality of gate electrode patterns in a peripheral circuit region of a semiconductor substrate on which an active area is defined;
forming an interlayer insulation layer on the gate electrode patterns;
forming a plurality of first contact holes through the interlayer insulation layer on both sides of the gate electrode pattern in an NMOS area of the peripheral circuit region by etching a predetermined portion of the interlayer insulation layer located above part of the active area defining the NMOS area, in an area-type manner to expose the gate electrode pattern in the NMOS area, the plurality of first contact holes self-aligned with the gate electrode pattern;
forming a plurality of N-type source/drain regions in the semiconductor substrate by implanting N-type dopant ions into the semiconductor substrate through the first contact holes;
forming a plurality of second contact holes through the interlayer insulation layer on both sides of the gate electrode pattern in a PMOS area of the peripheral circuit region by etching a predetermined portion of the interlayer insulation layer located above part of the active area defining the PMOS area, in an area-type manner to expose the gate electrode pattern in the PMOS area, the plurality of second contact holes self-aligned with the gate electrode pattern; and
forming a plurality of P-type source/drain regions in the semiconductor substrate by implanting P-type dopant ions into the semiconductor substrate through the second contact holes.

8. The method of claim 7, which further comprises forming a high-concentration N+impurity region in the N-type source/drain regions by implanting a high concentration of N⁺ ions into the semiconductor substrate through the first contact holes, after forming the N-type source/drain regions.

9. The method of claim 8, wherein the forming of the first contact holes, the forming of the N-type source/drain regions, and the forming of the high-concentration N⁺ impurity region are performed using the same photoresist pattern.

10. The method of claim 7, which further comprises forming a high-concentration P+impurity region in the P-type source/drain regions by implanting a high concentration of P⁺ ions into the semiconductor substrate through the second contact holes, after forming the P-type source/drain regions.

11. The method of claim 10, wherein the forming of the second contact holes, the forming of the P-type source/drain regions, and the forming of the high-concentration P⁺ impurity region are performed using the same photoresist pattern.

12. The method of claim 7, which further comprises:
depositing a conductive layer on the semiconductor substrate to fill the first and second contact holes; and
forming a plurality of first contact plugs that fill the respective first contact holes, a plurality of second contact plugs that fill the respective second contact holes, wherein bitlines that connect to the first and second contact plugs comprise one body by patterning the conductive layer.

13. The method of claim 7, wherein each of the gate electrode patterns comprise a gate insulation layer, a gate conductive layer, and a gate hard mask, and the forming of the second contact holes comprises forming a plurality of third contact holes that expose the gate conductive layer by etching the interlayer insulation layer and the gate hard mask.

14. The method of claim 13, which further comprises:
depositing a conductive layer on the semiconductor substrate to fill the first, second, and third contact holes; and
forming a plurality of first contact plugs that fill the respective first contact holes, a plurality of second contact plugs that fill the respective second contact holes, a plurality of third contact plugs that fill the respective third contact holes, wherein bitlines that connect to the first, second, and third contact plugs comprise one body by patterning the conductive layer.

15. A method of fabricating a semiconductor device comprising:
providing a semiconductor substrate having a cell region and a peripheral circuit region;
forming a device isolation layer to define an active area in the cell region and the peripheral circuit region of the semiconductor substrate;
forming a plurality of gate electrode patterns on the active area of the cell region and the peripheral circuit region, the gate electrode patterns each including a gate insulation layer, a gate conductive layer, and a gate hard mask;
forming a plurality of source/drain regions in the cell region of the semiconductor substrate between the plurality of gate electrode patterns;
forming a first interlayer insulation layer on the semiconductor substrate to fill spaces between the gate electrode patterns;
forming a plurality of self-aligned contact holes by etching the first interlayer insulation layer to expose the source/drain regions in the cell region;
forming a plurality of landing pads in the self-aligned contact holes;
forming a second interlayer insulation layer on the first interlayer insulation layer, the landing pads, and the gate electrode patterns;
forming a first photoresist pattern on the second interlayer insulation layer to expose the landing pads on the second interlayer insulation layer and to expose a portion of the second interlayer insulation layer located above the active area that defines an NMOS area of the peripheral circuit region in an area-type manner;
forming a plurality of bitline contact holes that expose the respective landing pads by etching the second interlayer insulation layer, using the first photoresist pattern as an etching mask, and forming a plurality of first contact holes on both sides of the gate electrode patterns in the NMOS area by etching the first and second interlayer insulation layers to expose the gate electrode patterns in the NMOS area, the plurality of first contact holes self-aligned with the gate electrode patterns;
forming N-type source/drain regions in the NMOS area by implanting N-type dopant ions at a first concentration into the semiconductor substrate, using the first photoresist pattern as an ion implantation mask, and forming a high-concentration N⁺ impurity region in each of the N-type source/drain regions by implanting a high concentration of N⁺ impurity ions at a second concentration into the semiconductor substrate, the second concentration being higher than the first concentration; and
removing the first photoresist pattern.

16. The method of claim 15 which further comprises:
forming a second photoresist pattern on the second interlayer insulation layer, the second photoresist pattern having an opening to expose a portion of the gate conductive layer in the peripheral circuit region and to expose a portion of the second interlayer insulation layer located above the active area that defines a PMOS area of the peripheral circuit region in the area-type manner;
forming a plurality of second contact holes on both sides of the gate electrode patterns in the PMOS area by etching the first and second interlayer insulation layers to expose the gate electrode patterns in the PMOS area, the second contact holes self-aligned with the gate electrode patterns, and forming a plurality of third contact holes to expose the gate conductive layer by etching portions of the second interlayer insulation layer and the gate hard mask;
forming a plurality of P-type source/drain regions in the NMOS area by implanting P-type dopant ions at a first concentration into the semiconductor substrate, using the second photoresist pattern as an ion implantation mask, and forming a high-concentration P⁺ impurity region in each of the P-type source/drain regions by implanting a high concentration of P⁺ impurity ions at a second concentration into the semiconductor substrate, the second concentration being greater than the first concentration; and
removing the second photoresist pattern.

17. The method of claim 16 which further comprises:
depositing a conductive layer on the semiconductor substrate to fill the first, second, and third contact holes; and
forming a plurality of first contact plugs that fill the respective first contact holes, a plurality of second contact plugs that fill the respective second contact holes, a plurality of third contact plugs that fill the respective third contact holes, wherein bitlines that connect to the first, second, and third contact plugs comprise one body by patterning the conductive layer.

18. The method of claim 17, wherein the forming of the bitline comprises etching the conductive layer until the gate hard mask is exposed.

19. The method of claim 15 which further comprises reflowing the first interlayer insulation layer and the second interlayer insulation layer before forming the first contact holes.

20. The method of claim 15 which further comprises annealing the landing pads before forming the first contact holes.
